(19) United States
(12) Patent Application Publication
(10) Pub. No.: US 2018/0054108 A1
(43) Pub. Date: Feb. 22, 2018

(54) DRIVE SYSTEM COMPRISING AT LEAST ONE HEAT PIPE, AND THE USE OF SAME IN A DRIVE SYSTEM

(71) Applicant: AMK ARNOLD MÜLLER GMBH & CO. KG, 73230 Kirchheim unter Teck (DE)

(72) Inventors: Eberhard MÜLLER, Kirchheim/Teck (DE); Uwe GONSER, Kirchheim/Teck (DE)

(73) Assignee: AMK ARNOLD MÜLLER GMBH & CO. KG, 73230 Kirchheim unter Teck (DE)

(21) Appl. No.: 15/555,526

(22) PCT Filed: Feb. 13, 2016
(86) PCT No.: PCT/EP2016/000247

§ 371 Date: Sep. 4, 2017

(30) Foreign Application Priority Data
Mar. 5, 2015 (DE) 10 2015 002 768.9

(51) Int. Cl. H02K 9/20; H05K 7/20; H02K 11/33; F28F 1/12

(52) U.S. Cl. CPC H02K 9/20; H05K 7/20309; H05K 7/20318; F28F 1/124; H05K 7/20936; H02K 11/33; H05K 7/20336

(57) ABSTRACT

A drive system includes at least one drive unit, and at least one control device which at least partially influences the functionality of the drive unit and is connected to the drive unit along a connection region such that a thermal bridge is formed, and wherein the waste heat produced inside the thermal bridge during operation of the system, caused by the respective operating temperature of the drive unit and/or control device, can be discharged from the connection region by at least one heat pipe.

The invention relates to a drive system consisting of at least one drive unit and at least one control device at least partially influencing the operation of the drive unit, which is connected to the drive unit along a connection area to form a thermal bridge.

Drive systems, in particular electrical drive systems in the manner of servo motors, which can also consist of drive unit and open-loop and/or closed-loop control devices at least partially influencing the operation of the drive unit as a handleable structural unit, are known in many designs.

DE 10 2006 027 566 A1 describes a drive system having a drive unit formed as an external rotor motor, with the rotary angle position of the rotor being determined by means of an angle sensor. The angle sensor is part of a control device of the drive system. Drive systems of this type are used for example in mechanical and plant engineering for any actuating purposes, as drive units for machine tools, in production lines for the automotive industry, in the textile industry, or in presses.

Electrical servo motors of differing performance classes and designs for positioning and actuating purposes, and also for use as a variable-speed drive for continuous running preferably at low and medium speeds, are known from various company brochures of the property right owner. The housings of these servo motors are provided with a convection or liquid cooling device for removing lost heat and for achieving constant operating conditions in the servo motors. Furthermore, servo motors with integrated servo controller are known from these company brochures and form electronically independent drive modules usable for many applications.

DE 10 2012 013 447 A1 describes a construction kit with a preferably electric basic module that can be provided with various function elements from a group of add-on modules.

Provided as add-on modules are, for example, an electric motor or a cooling plate through which can flow a cooling fluid, in particular a cooling liquid, or a cooling housing designed to cover an in particular electric motor and provided with a cooling system integral to the housing. With construction kits designed in this way, ready-to-connect and compact units can be constructed for installation directly in machines, on shafts to be driven or the like.

The fluid cooling systems known for drive systems of this type have room for improvement, in particular regarding their installation space requirement and their demands on the surroundings of the drive system, such as unobstructed flow paths for cooling air and the like.

In view of this, the object underlying the invention is to provide a drive system which in addition to a minimised installation space requirement has an at least approximately constant and preselectable operating temperature. This object is achieved with a drive system having all the features of patent claim 1.

The drive system in accordance with the invention is characterised in that the waste heat generated inside the thermal bridge during operation of the drive system and caused by the respective operating temperatures of the drive unit and/or control device, is selectively removable from the connection area of drive unit and control device by means of at least one heat pipe. This creates a drive system in which waste heat both from the drive unit and from its control device is removable simultaneously by means of a thermal transport element operating preferably without auxiliary power, and the operating temperature of the drive unit and of the control device is thereby settable to a preselectable value. As a result, a space-saving and dependably and precisely operating drive system is created, whose control device is effectively protected from damaging operating temperatures of the motor.

The heat pipe used in accordance with the invention is a thermal transport element that uses an evaporation/condensation process for thermal transport and achieves in comparison to other known thermal transport devices, in particular cooling devices, a substantially higher heat flux density. Using a heat pipe, it is thus possible to convey large heat quantities on small cross-sectional surfaces.

In heat pipes, a distinction is made between two main designs, i.e. the heat pipe proper and the two-phase thermosiphon. A heat pipe can be characterised as an evacuated system with vacuum-tight sealing, whose inner walls are provided with a capillary structure that is saturated with a heat carrier. If the system is supplied with heat at one point, the heat carrier evaporates out of the capillary structure and the vapour flows to a cooled point, condenses there and in so doing releases its evaporation heat. The condensate is then returned by capillary forces in the capillary structure to the place of evaporation (U.S. Pat. No. 3,229,759 A) and a new cycle can commence, with these processes of evaporation and condensation being continuous.

The closed two-phase thermosiphon is also termed a gravity-assisted heat pipe, gravitation or gravity heat pipe, wickless heat pipe or as a heat pipe without capillary structure. Unlike in the heat pipe, there is a liquid sump. When heat is supplied in the heating zone, the container boils, the sump bubbles up, vapour flows to the cooling zone, and a condensation film flows back out of it. Depending on the type of capillary structure selected, condensate can also be conveyed against gravity in a heat pipe without auxiliary power, permitting positional independence in a drive system equipped with such a heat pipe when it is installed.

In a particularly preferred design of the drive system, the respective heat pipe is split at least into an evaporator and a condenser area, and the evaporator area is arranged inside the connection area and the condenser area outside the latter. This results in a solution for closed-loop control of an operating temperature of a drive system that is simple and inexpensive in comparison to the use of heat pipe heat exchangers having several heat pipes. To increase the heat transmission of the heat pipe in the condenser area, a heat exchanger can advantageously be provided which is in heat-conducting contact with the condenser area and hence forms a further unit part of the drive system.

In a further advantageous embodiment of the drive system, the heat pipe can be thermally insulated from the drive unit by means of a thermal insulation in order to minimise the heat transmission from the drive unit to the control device via the heat pipe.

The drive unit can be driven with the aid of a liquid or gaseous pressurising medium, but the drive unit is preferably designed as an electrically drivable servo and/or actuator motor in the manner of a synchronous or asynchronous machine containing an appropriately heat-sensitive power electronic unit, where the heat exchanger arranged in heat-conducting contact on the condenser area of the heat pipe consists of a plate-like basic cooling element from which protrude finger-like or plate-like cooling fins which each lead with their free ends into the surroundings of the drive system. Thanks to this embodiment of the drive system, particularly operationally reliable and efficient cooling of the power electronic unit and also of the drive unit can be provided constructed with an installation space requirement of the total drive system that is reduced in comparison to the prior art.

On account of the advantageous function principle of a heat pipe, it is possible in a particularly preferred exemplary embodiment to design the heat pipe bent at approximately a right angle, where at the location of the bend the heat pipe exits with its evaporator area the connection area forming the thermal bridge between drive unit and control device and enters with its condenser area a further connection area forming a further thermal bridge between drive unit and heat exchanger.

In a preferred embodiment of the drive unit, the heat pipe leads at the point of its at least approximately right-angled bend outwards into the surroundings and faces inwards a rear housing face of the drive unit, whose front housing face is passed through by a drive shaft. This permits operation of third components undisrupted by heat removal, and the drive unit can be fixed on such third components without disruption, preferably with its unobstructed end face through which passes the drive shaft.

To provide a drive system particularly adaptable to a wide range of add-on situations of a machine, the control device is advantageously mounted stationary, without projecting, preferably recessed by a preselectable distance, on an outer housing side of the drive unit by connection webs, where said connection webs limit the connection area and at least partially the thermal bridge. In this way, a heat-releasing surface is left free on the upper side of the drive unit by the control device, permitting additional convective heat radiation.

To achieve a particularly efficient heat removal via a heat exchanger, this heat exchanger is advantageously arranged in full surface contact on the rear housing face of the drive unit and preferably covers the latter completely. The heat exchanger can be mounted stationary by means of further connection webs, forming a further connection area, on a connection surface of a machine housing or the like preferably permitting a further heat dissipation.

To permit good heat conduction from the drive unit to the heat pipe, in a particularly preferred exemplary embodiment at least part of the housing of the drive unit is formed from an element made in a die-casting process or by means of a pultrusion or extrusion method, with aluminium or zinc being used as housing materials.

The invention further provides for a use of a heat pipe in a drive system in accordance with the invention for protecting the control device with its heat-sensitive power electronic unit from the operating temperature of the drive unit having a detrimental and possibly damaging effect on the power electronic unit. Further advantages and features of the invention are shown in the figures and in the following description of the drawing. It is shown in a schematic and not-to-scale representation in

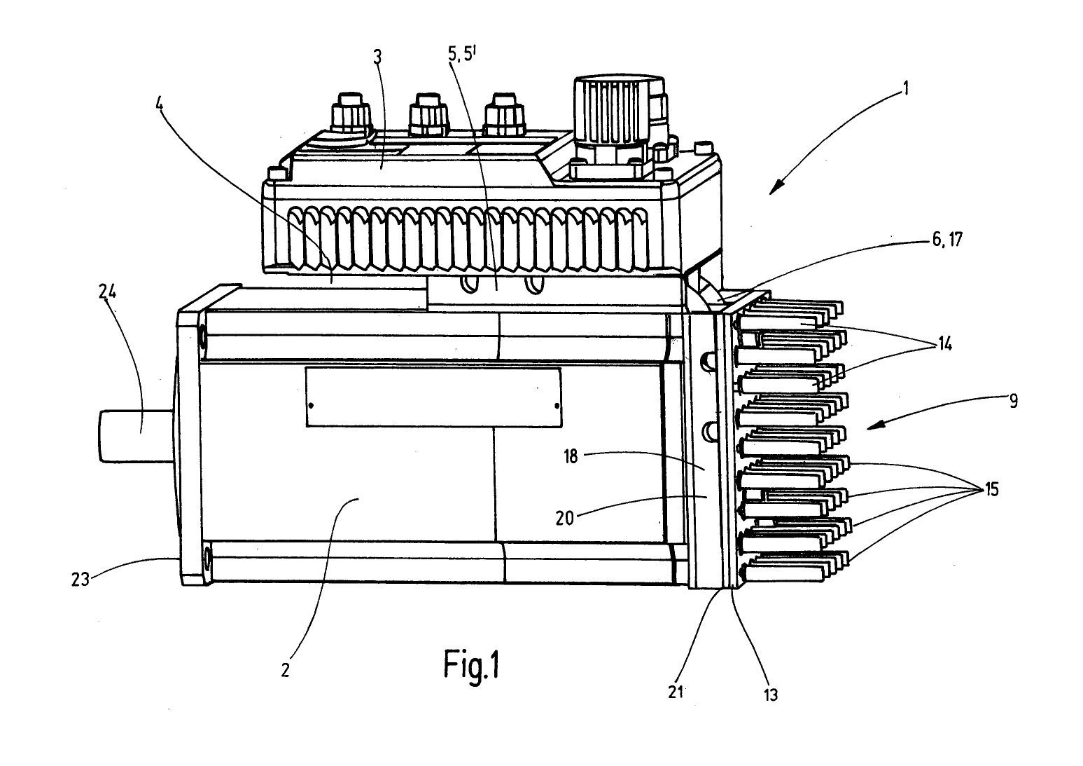

FIG. 1 a perspective view onto a drive system in accordance with the invention;

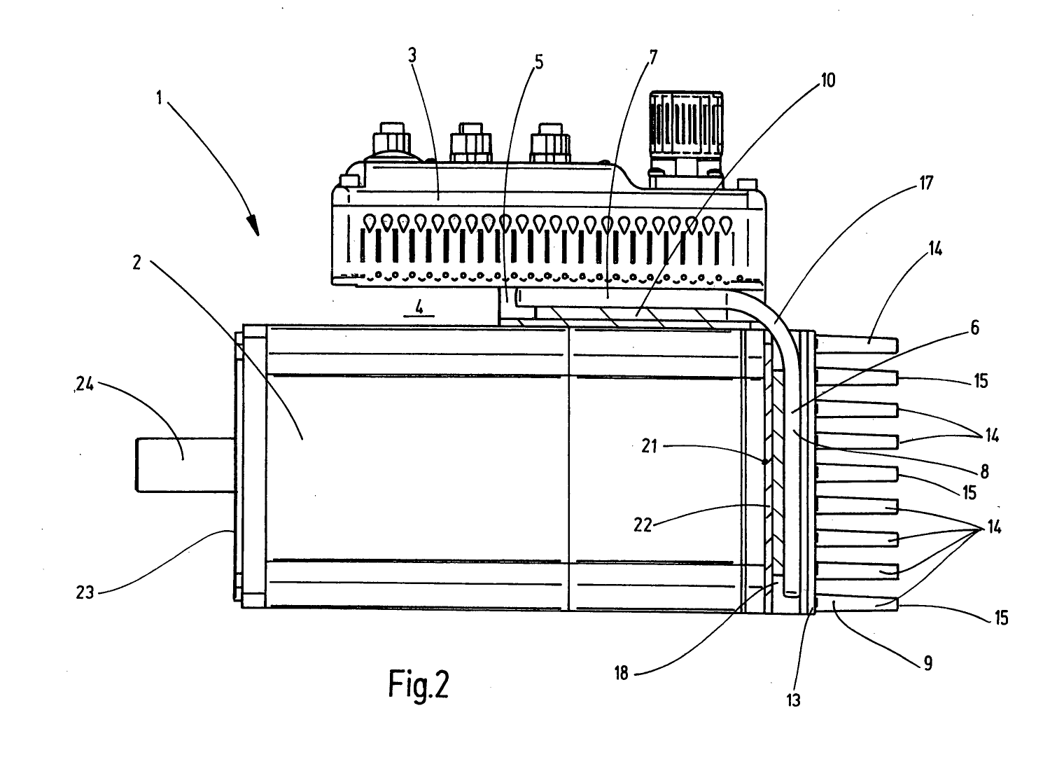

FIG. 2 a side view onto the drive system according to FIG. 1, with partial sectional representation of a heat pipe system as a heat compensation means.

FIG. 1 shows a perspective view onto the drive system in accordance with the invention 1 as a whole, substantially consisting of a drive unit 2 in the manner of an electric servo motor, intended as standard for positioning and actuating purposes of third components (not shown) and of a control device 3 at least partially controlling the drive unit 2, designed preferably in the manner of a high-power electronic unit. The drive system 1 is also designed for application in problematic cooling situations, caused for example by a high integration density of system components at the place of use or by a high ambient temperature prevailing there.

The control device 3 in the exemplary embodiment shown, arranged on an upper side of the drive unit 2 and for space-saving reasons at the lowest possible distance from said unit 2, is connected to the drive unit 2 along a connection area 5 to form a thermal bridge 4. The connection area 5 extends over a partial length, preferably over about half the length of the drive unit 2 when seen in the axial direction, and is accordingly designed shorter than the heat transition area forming the thermal bridge between drive unit 2 and control device 3. For connecting the two said components of the drive system 2 to one another, at least one rail 5′, U-shaped or L-shaped when seen in cross-section, is provided and is preferably formed from a material with low thermal conductivity, where the control device 3 is detachably connected to the drive unit 2 by the rail connection area, but is otherwise stationary. Preferably, however, a pair of rails 5′ running parallel to one another is provided, in order to mount the control device 3 on the drive unit 2.

The drive system 1 has in accordance with the invention between the control device 3 and the drive unit 2 a heat pipe 6 which, as shown in particular in FIG. 2, extends with its evaporator area 7 along the connection area 5. The heat pipe 6 is arranged inside an unobstructed, channel-like cross-section defined by the respective fixing rail 5′, and protected from mechanical damage during assembly and operation of the drive system 1. With the aid of the heat pipe 6, the heat generated inside the thermal bridge 4, in particular waste heat, and caused by the respective operating temperature of the drive unit 2, is removable from the connection area 5, where a constant holding down of the operating temperature of the control device 3 is permitted by the selected technical parameters of the heat pipe 6 and by the physical material characteristics of the heat carrier fluid enclosed in the heat pipe 6, regardless of the power output of the drive unit 2 varying in time. The drive unit 2 can, for instance, readily achieve during operation a temperature of 150° C. and more radiated via its housing, which would, without the heat pipe temperature dissipation in accordance with the invention, damage the temperature-sensitive electronic control unit, in particular the high-power electronic unit of the control device 3, which can be regularly subjected to a maximum temperature of 70° C. for trouble-free operation.

The heat pipe 6 provided for the thermal transport to achieve that effect is an evacuated system with vacuum-tight sealing, whose inner walls are provided with a capillary structure saturated with a heat carrier fluid. The heat pipe 6 operates without a supply of drive power, except that from the heat supplied from the outside, predominantly originating from the drive unit 2. However, with a reduced motor power or switched-off drive unit 2, any excess heat quantities in the area of the thermal bridge 4 can likewise be removed via the respective heat pipe 6 and can also originate from the cooling-down control device 3.

As FIG. 2 shows, the heat pipe 6 is split into the evaporator area 7 and a condenser area 8 adjoining it in one piece, where the evaporator area 7, as mentioned, is arranged inside the connection area 5 and the condenser area 8 outside said connection area 5. The heat generated at the evaporator area 7, which is mainly due to the power losses of the drive unit 2 during operation, leads to evaporation of the heat carrier fluids out of the capillary structure of the evaporator area 7 of the heat pipe 6, where the vapour flows inside the heat pipe 6 to the condenser area 8. The condenser area 8 of the heat pipe 6 is here preferably in a heat-conducting, in particular heat-removing contact with a heat exchanger 9, which is an integral part of the drive system 1 and whose design andoperation are described in more detail in the following.

To prevent in addition any damaging heat transmission from the drive unit 2 to the control device 3 via the connection area 5 as part of the thermal bridge 4, a thermal insulation 10 is provided, for example formed from a heat-resistant plate material, running at a distance from and parallel to the heat pipe 6 on the upper side of the drive unit 2 and in contact therewith. Due to the distance, a kind of air gap is formed, which is a poor transmitter of heat, so that in addition to the heat pipe 6 a further thermal disconnection between the drive unit 2 and the control device 3 is created.

The drive unit 2 is designed as a servo motor in the manner of an electrically drivable synchronous machine, and the control device 3 for example in the manner of an integrated servo controller, which includes the power electronic unit 13 for controlling the rotation direction, the speed and a holding torque of the drive unit 2 and which is known to also generate heat losses during operation which have to be removed, for which purpose the heat pipe 6 can be used among others.

The heat exchanger 9 consists of a full-surface and plate-like basic cooling element 13 from which cooling fins 14 protrude vertically and project with their respective free ends 15 into the surroundings of the drive system 1, and which in the exemplary embodiment shown are designed finger-like, but can also be designed plate-like or in another suitable form. The cooling fins 14 have about five to ten times the length relative to the thickness of the plate-like basic cooling element 13.

To design the drive unit 2 particularly compact, the heat pipe 6 is bent at a right angle. It therefore has at its transition area between the evaporator area 7 and the condenser area 8 a bend 17 at which it exits with its evaporator area 7 and enters with its condenser area 8 a connection area 19 forming a further thermal bridge 18 between the heat pipe 6 and the heat exchanger 9. Hence the entire condenser area 8 of the heat pipe 6 is substantially arranged in contact with the heat exchanger 9 in the area of its basic cooling element 13 and otherwise an effective spatial disconnection is achieved between the heat-receiving evaporator area 7 and the heat-emitting condenser area 8 by the bend 17 and the heat pipe system connected thereto, permitting trouble-free and efficient operation.

The heat exchanger 9 is in turn connected, by pairs of opposite rail sections 20 designed comparably to the rails 5′, to the rear wall of the drive unit 2 as the rear housing face 21, and said rail sections help to define the spatial extent of the further second connection area 19, into which the condenser area 8 of the heat pipe 6 enters, said heat pipe with its lower free end terminating substantially flush with the common underside of drive unit 2 and heat exchanger 9. Also, a further plate-like thermal insulation 22 extending substantially along the rear housing face 21 is in turn preferably attached for a thermal disconnection between the condenser area 8 of the heat pipe 6 and the housing face 21.

At the point of the bend 17 of the heat pipe 6, the latter leads outwards into the surroundings and faces in its course inwards towards the rear housing face 21 of the drive unit 2. The front and opposite housing face 23 is passed through by a drive shaft 24 of the servo motor.

For better heat conduction, at least part of the surrounding housing of the drive unit 2 is formed from an element manufactured in a die-casting process or is manufactured from an extruded section, with aluminium or zinc being preferably used as housing materials.

Due to the use of a heat pipe 6, the thermal transport in terms of heat quantity and speed of heat conduction can be increased by 100 to 1000 times in comparison with a solid copper conductor. Heat pipes 6 are fully functional even with very small dimensions (diameters from about 10 to 500 mm), whereby an advantageous drive system 1 is obtained which can remove heat originating from the control device 3 and from the drive unit 2 that can impair functional dependability, while nevertheless achieving a compact design of the drive system 1. If required, it is also possible to use several heat pipes 6 arranged adjacent or behind one another (not shown).

In particular, with the drive system 1 in accordance with the invention an add-on module is achieved which if required can be fixed on almost any third components to be driven. Due to the thermally disconnected design, the control intelligence can be combined in decentralised manner with the drive unit 2 on the spot, and it is no longer necessary to perform from a central position, as a rule in the form of a switch cabinet accommodating the control devices, centralised control and operation of the drive unit 2 used in a machine by an expensively achieved wiring system. This has no equivalent in the prior art.

1. Drive system, comprising at least one drive unit and at least one control device at least partially influencing the operation of the drive unit, which is connected to the drive unit along a connection area to form a thermal bridge, comprising at least one heat pipe to remove the waste heat generated inside the thermal bridge during operation of the system inside the thermal bridge and caused by the respective operating temperatures of the drive unit and/or the control device, wherein the heat pipe is split at least into an evaporator area and a condenser area, and the evaporator area is arranged inside the connection area and the condenser area outside the latter, and wherein the condenser area of the heat pipe is heat-conducting contact with at least one heat exchanger which as a further unit part is an integral part of the drive system.

2-3. (canceled)

4. Drive system according to claim 1, wherein at least one heat pipe is separated by means of a thermal insulation (10) at least from the drive unit.

5. Drive system according to claim 1, wherein the drive unit is an electrically drivable servo and/or actuator motor, the control device contains a heat-sensitive power electronic unit, and the heat exchanger comprises a plate-like basic cooling element, from which protrude finger-like cooling fins which each lead with their free ends into the surroundings.

6. Drive system according to claim 1, wherein at least one heat pipe is bent at a right angle and at the location of the bend exits with its evaporator area the connection area forming the thermal bridge between drive unit and control device and enters with its condenser area a further connection area forming a further thermal bridge between drive unit and heat exchanger.

7. Drive system according to claim 1, wherein at the location of the bend of the heat pipe the latter leads outwards into the surroundings and faces inwards a rear housing face of the drive unit, whose front housing face is passed through by a drive shaft.

8. Drive system according to claim 1, wherein the control device is mounted stationary, without projecting, preferably recessed by a preselectable distance, on an outer housing side of the drive unit by connection webs which limit the connection area and at least partially the thermal bridge.

9. Drive system according to claim 1, wherein the heat exchanger completely covers the rear housing face of the drive unit and is mounted stationary there by means of further connection webs.

10. Drive system according to claim 1, wherein at least part of the housing of the drive unit comprises at least one element manufactured in a die-casting process or is manufactured from an extruded section, and in that aluminium or zinc are preferably used as housing materials.

11. Drive system according to claim 1, wherein the heat pipe is designed as a heat pipe.

12. Use of at least one heat pipe in a drive system according to claim 1 for protecting the control device with its heat-sensitive power electronic unit from the operating temperature of the drive unit having a detrimental and possibly damaging effect on the power electronic unit.
